(19) United States
(12) Patent Application Publication
(10) Pub. No.: US 2005/0045091 A1
(43) Pub. Date: Mar. 3, 2005

(54) Molecular beam epitaxy growth apparatus and method of controlling same

(75) Inventor: Takashi Kawasaki, Kashiba-shi (JP)

Correspondence Address: NIXON & VANDERHYE, PC, 1100 N GLEBE ROAD, 8TH FLOOR, ARLINGTON, VA, 22201-4714, US

(73) Assignee: Sharp Kabushiki Kaisha, Osaka (JP)

(21) Appl. No.: 10/915,321

(22) Filed: Aug. 11, 2004

(30) Foreign Application Priority Data
Aug. 25, 2003 (JP) 2003-300078

(51) Int. Cl. C30B 23/00; C30B 25/00; C30B 28/12; C30B 28/14; C30B 1/00

(52) U.S. Cl. 117/89

(57) ABSTRACT

In system(s) utilizing multiple molecular beams of Group V material(s) (and/or Group VI material(s)), rotary beam chopper(s)) 8 and so forth are installed in front of respective discharge port(s) of such plurality of Group V molecular beam source cell(s) 5, 6 (and/or Group VI molecular beam source cell(s)); intermittency control causing molecular beam(s)) discharged from respective molecular beam source cell(s) 5, 6 to be repeatedly blocked and discharged in periodic fashion is carried out; and mutual synchronization of such molecular beam(s)) subjected to intermittency control causes supply of respective molecular beam(s)) of multiple Group V materials (and/or Group VI materials) in sufficient quantity or quantities as necessary for crystal growth, with alloy ratio(s) within crystal(s) being efficiently controlled.

### CLAIM(S) IN CONNECTION WITH RELATED APPLICATION(S) AND/OR PRIORITY RIGHT(S)

This application claims priority under 35 USC 119(a) to Patent Application No. 2003-300078 filed in Japan on 25 Aug. 2003, the content of which is incorporated herein by reference in its entirety.

### BACKGROUND OF THE INVENTION

The present invention relates to molecular beam epitaxy (MBE) growth apparatus and method of controlling same.

Structure of a typical molecular beam epitaxy growth apparatus (MBE apparatus) is shown in FIG. 9.

The molecular beam epitaxy growth apparatus shown in FIG. 9 is equipped with vacuum chamber 101 which can be evacuated to ultrahigh vacuum; substrate manipulator 102 which heats and rotates substrate 200 as substrate 200 is held at a prescribed location within this vacuum chamber 101; a plurality of molecular beam source cells 103, 104, 105, 106 radiating molecular beams toward the surface of substrate 200; and cell shutters 107 respectively installed at the fronts of the respective cell discharge ports. This apparatus might be such as to cause metallic gallium (Ga) and arsenic (As), for example, to be heated and vaporized so as to be radiated in the form of molecular beams from molecular beam source cells 103 . . . 106 to the surface of substrate 200, causing crystal(s) to be epitaxially grown on the surface of substrate 200. An advantage of crystal growth using MBE techniques such as this is that it is possible to obtain sharp heterointerfaces(s) to precision(s) on the atomic-layer level through rapid discharge and/or blocking of precursor material.

For example, where gallium arsenide (GaAs) crystal(s) is/are to be grown, a sufficient quantity of arsenic that has been heated and vaporized at molecular beam source cell(s) might be supplied to substrate 200; and with the system in this state, during supply of metallic gallium that has been heated and vaporized at molecular beam source cell(s), opening and/or closing of cell shutters installed at front(s) of respective molecular beam source cell(s) could make it possible to control growth to a precision which is on the atomic-layer level.

Furthermore, another crystal growth technique is the method of using a MOVPE apparatus to directly form GaInAsP semiconductor optical waveguide structures as disclosed for example at Japanese Patent Application Publication Kokai No. 2000-187127 (hereinafter “Patent Reference No. 1”). The procedure described in this Patent Reference No. 1 concerns use of a MOVPE apparatus to grow GaInAsP crystals, the method being such that intermittent supply of Group III precursor material permits promotion of migration on substrate of supplied precursor material in the intervals between times when precursor material is not being supplied. Note also that the technique described in this Patent Reference No. 1 employs selective MOVPE to form GaInAsP semiconductor optical waveguide structures.

Use of these GaInAsP crystals is not limited to such optical waveguides; inasmuch as they are crystals that do not contain Al—which tends to cause device deterioration—they may also be effectively used in luminescent layers for infrared lasers. While satisfactory semiconductor crystals as might be used in infrared lasers and other such compound semiconductor laser elements may be obtained through epitaxial growth using MBE or MOVPE, employment of MBE will generally better permit satisfactory crystals having few defects to be obtained. That is, because MBE permits sharp heterointerfaces to be obtained as described above, crystals of good quality when considered for use as laser elements may be obtained. When growing crystals for formation of active layers in laser elements, control of the alloy ratios of the respective elements within the crystal is an important issue for causing the laser to emit at constant wavelength.

When using MBE to epitaxially grow Groups III-V crystals, substrate temperature is increased, preventing deposition onto substrate of Group V material by itself, at which time Group III material molecular beam(s) is/are controlled while Group V material molecular beam(s) is/are continuously supplied in sufficient quantity or quantities. For example, when growing GaInP crystals, a method might be adopted in which the ratio between Ga and In within crystal is/are adjusted by controlling Ga and In molecular beam source cell temperatures while P molecular beam(s) is/are continuously supplied in sufficient quantity or quantities. However, in the case of crystals containing a plurality of Group V materials such as GaInAsP, the fact that As and P molecular beams are supplied in sufficient quantities makes it difficult to control the ratio between As and P within crystal.

The present invention was conceived in light of such situation, it being an object thereof to provide a molecular beam epitaxy growth apparatus, and method of controlling same, permitting easy and efficient control of alloy ratio(s) within crystal(s) when using molecular beam epitaxy to crystallize and grow Groups II-VI compound semiconductor(s) and/or Groups III-V compound semiconductor(s).

### SUMMARY OF INVENTION

A preferred embodiment of the present invention is a molecular beam epitaxy growth apparatus causing one or more crystals to be grown on one or more substrate surfaces as a result of radiation of one or more molecular beams from a plurality of molecular beam source cells onto at least one of the substrate surface or surfaces, the molecular beam epitaxy growth apparatus comprising one or more control mechanisms controlling molecular beam radiation and/or interruption so as to cause intermittent radiation of at least one of the molecular beam or beams from at least a portion of the plurality of molecular beam source cells; and controlling radiation and/or interruption of at least a portion of the molecular beams from at least a portion of the plurality of molecular beam source cells so as to be mutually substantially synchronous and/or have substantially identical periods at the molecular beam source cells.

In accordance with the foregoing constitution, molecular beam(s) is/are subjected to intermittency control and is/are supplied to substrate surface(s) in alternating fashion, as a result of which easy and effective control of alloy ratio(s) of atom(s) of material(s) within crystal(s) is permitted while molecular beam material(s) is/are supplied in sufficient quantity or quantities from molecular beam source cell(s). Furthermore, by carrying out control so as to cause intermittency control of multiple molecular beams to be substantially synchronous and/or have substantially identical periods, it is possible to achieve a situation such that any material(s) is/are always present at substrate surface(s), there being no lack of material(s) thereat, as if continuous supply of material(s) was taking place.

In a molecular beam epitaxy growth apparatus according to embodiment(s) of the present invention, it is preferred that at least one of the control mechanism or mechanisms possess one or more beam choppers having one or more rotating vane assemblies causing intermittent radiation of at least one of the molecular beam or beams.

Employment of such rotary beam chopper(s) will make it possible to supply molecular beam(s) with rapid, stable, and highly reliable intermittency control.

In a molecular beam epitaxy growth apparatus according to embodiment(s) of the present invention, at least one of the rotating vane assembly or assemblies of at least one of the beam chopper or choppers may be more or less in the form of a disk having one or more cutouts; and at least a portion of the rotating vane assembly or assemblies may be arranged such that rotation of at least a portion of the rotating vane assembly or assemblies causes at least a portion of the cutout or cutouts to be presented at prescribed period(s) along path(s) traveled by molecular beam(s) from molecular beam source cell(s). Furthermore, as beam chopper(s), structure(s) comprising at least two rotating vane assemblies, each of which is in the form of a disk having one or more cutouts, the at least two rotating vane assemblies being arranged in more or less coaxial fashion (on the same rotating shaft(s)), may be employed.

Use of rotary beam chopper(s) equipped with rotating vane assemblies formed in such fashion will make it possible for center(s) of rotation and center(s) of mass of rotating portion(s) to be made to coincide. For example, because configuration(s) such as those shown in FIG. 4 are such that center(s) of mass of rotating vane assembly or assemblies and of rotation may be made to coincide, it is possible to prevent vibration and/or loss in torque due to wobble.

A molecular beam epitaxy growth apparatus according to embodiment(s) of the present invention may employ as drive transmission mechanism a constitution in which at least one magnetically coupled rotary feedthrough rotating at least one of the rotating vane assembly or assemblies is provided; wherein at least one period at which one or more magnets within at least one of the rotary feedthrough or feedthroughs are arranged is made to substantially agree with at least one period at which at least a portion of the cutout or cutouts of at least one of the rotating vane assembly or assemblies is arranged.

When using magnetically coupled rotary feedthrough(s) in such fashion, by causing period(s) at which magnet(s) within rotary feedthrough(s) is/are arranged in direction(s) of rotation to be made to substantially agree with period(s) of beam chopper rotating vane assembly or assemblies, even where magnetic coupler(s) installed at the atmospheric side (outside the vacuum chamber) is/are removed therefrom it will nonetheless be possible to attach same with good reproduceability.

The relative amounts of molecular beam radiation versus interruption during use of rotary beam chopper(s) subjected to intermittency control may be controlled by controlling fractional angles (fractional areas) occupied by rotating vane assembly cutout(s) versus occluding portion(s). For example, installing two or more rotating vane assemblies 581, 582 of configuration(s) as shown in FIGS. 5 and 6 in coaxial fashion (on the same rotating shaft) will make it possible to alter in nonstepwise fashion the relative temporal durations of molecular beam radiation versus interruption.

Through use of molecular beam epitaxy growth apparatus(es) equipped with molecular beam control mechanism(s) such as have been described above it will be possible to fabricate crystals having layer(s) such as GaInAsP, for example, with sharp heterointerfaces.

Molecular beam epitaxy growth apparatus(es) according to embodiment(s) of the present invention is/are suited to crystallization and growth of Groups II-VI compound semiconductor(s) and/or Groups III-V compound semiconductor(s); and in the event that such Groups II-VI compound semiconductor(s) and/or Groups III-V compound semiconductor(s) is/are to be crystallized and grown, constitution may be such that Group II material molecular beam(s) and/or Group III material molecular beam(s) is/are continuously radiated from molecular beam source cell(s), and Group VI material molecular beam(s) and/or Group V material molecular beam(s) is/are intermittently radiated from molecular beam source cell(s).

A method of controlling one or more molecular beam epitaxy growth apparatuses according to embodiment(s) of the present invention may be such that at least one period of intermittency of at least one of the intermittently radiated molecular beam or beams is controlled so as to be not more than 8 seconds.

Embodiment(s) of the present invention may be particularly effective in the context of laser elements and other such systems employing Groups III-V compound semiconductor material(s) and/or Groups II-VI compound semiconductor material(s) for which sharp heterointerface(s) to precision(s) on the atomic level is/are sought.

When making use of epitaxial growth to grow Groups III-V crystal(s) in system(s) employing compound semiconductor material(s), crystallization and growth can be controlled by adjusting amount(s) of Group III material(s) supplied in molecular beam(s) while Group V material molecular beam(s) is/are supplied in sufficient quantity or quantities. When growing Groups II-VI crystal(s), crystallization and growth can be controlled by adjusting amount(s) of Group II material(s) supplied in molecular beam(s) while Group VI material molecular beam(s) is/are supplied in sufficient quantity or quantities. In such situations as well, use of intermittency control for control of molecular beam(s) of Group V and/or Group VI sublimable nonmetallic element(s) will make it possible to effectively adjust alloy ratio(s) within crystal(s) while molecular beam(s) is/are supplied in sufficient quantity or quantities. This will make it possible to obtain good-quality GaInAsP crystal(s) and/or GaInP crystal(s).

When molecular beam epitaxy growth apparatus(es) is/are used to grow crystal(s), growth might typically be carried out at deposition rate(s) of 0.5 to 4 μ/hour. When carrying out epitaxial growth at a deposition rate of 4 μ/hour, a single-atom layer might be grown in approximately 0.5 second. And when carrying out epitaxial growth at a deposition rate of 0.5 μ/hour, a single-atom layer might be grown in approximately 4 seconds.

In embodiment(s) of the present invention where molecular beam(s) is/are being pulsed for intermittency control, it is preferred in order to obtain uniform crystal(s) that at least two atomic layers be grown per cycle. Accordingly, where deposition rate is 0.5 μ/hour, carrying out control such that period(s) is/are not more than 8 seconds might make it possible to obtain uniform crystal(s); and similar effect might be obtained by carrying out control such that period(s) is/are not more than 4 seconds where deposition rate is 1 μ/hour, and/or by carrying out control such that period(s) is/are not more than 1 second where deposition rate is 4 μ/hour.

Furthermore, causing period(s) of intermittency to be such that not less than one cycle goes by during time(s) taken to grow single-atom layer(s) may permit growth of crystal(s) which is/are even more uniform. Moreover, while control permitting switching at rate(s) sufficiently fast relative to time(s) during which single-atom layer(s) is/are being formed will also be effective, efficient control of alloy ratio(s) will be impossible where there is inadequate ability to exhaust molecule(s) remaining in vicinity or vicinities of substrate surface(s).

### BRIEF DESCRIPTION OF DRAWINGS

FIG. 1 is a front view showing in schematic fashion a constitution of a molecular beam epitaxy growth apparatus in accordance with one embodiment of the present invention.

FIG. 2 is an oblique view of a beam chopper and a rotary feedthrough employed in the molecular beam epitaxy growth apparatus of FIG. 1.

FIG. 3 is a front view showing only a rotating vane assembly that has been extracted from the beam chopper of FIG. 2.

FIG. 4 (A) is a front view showing another example of a rotating vane assembly for a beam chopper; FIG. 4 (B) is a front view showing yet another example of a rotating vane assembly for a beam chopper; FIG. 4 (C) is a front view showing a different example of a rotating vane assembly for a beam chopper; and FIG. 4 (D) is a front view showing yet a different example of a rotating vane assembly for a beam chopper.

FIG. 5 is an oblique view showing yet another example of a beam chopper.

FIG. 6 is a front view showing only the rotating vane assemblies of the beam chopper of FIG. 5.

FIG. 7 is a front view showing in schematic fashion another constitution for a molecular beam epitaxy growth apparatus in accordance with the present invention.

FIG. 8 is a plan view showing in schematic fashion another constitution for a molecular beam epitaxy growth apparatus in accordance with the present invention.

FIG. 9 is a front view showing in schematic fashion a representative constitution of a molecular beam epitaxy growth apparatus in a prior art.

### DESCRIPTION OF PREFERRED EMBODIMENTS

Below, embodiments of the present invention are described with reference to the drawings.

### EMBODIMENT 1

### Overview of Molecular Beam Epitaxy Growth Apparatus

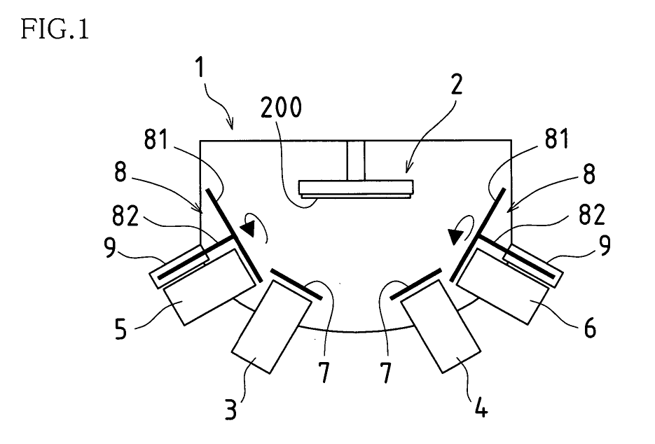

FIG. 1 is a drawing showing in schematic fashion an example of a molecular beam epitaxy growth apparatus in accordance with the embodiment 1.

The molecular beam epitaxy growth apparatus of the present example is equipped with vacuum chamber 1, substrate manipulator 2, Ga cell (Group III molecular beam source cell) 3, In cell (Group III molecular beam source cell) 4, As cell (Group V molecular beam source cell) 5, P cell (Group V molecular beam source cell) 6, and so forth.

Vacuum chamber 1 is evacuated to 2×10⁻⁹ Pa with all heater(s) (not shown) turned OFF. Substrate manipulator 2 is installed in the upper central region of vacuum chamber 1.

Substrate manipulator 2 has built thereinto substrate heating mechanism(s) and substrate rotating mechanism(s) (neither of which is shown), permitting substrate 200, which is held by this substrate manipulator 2, to be maintained at constant temperature and to be rotated at constant speed.

Respective cells—these being Ga cell 3, In cell 4, As cell 5, and P cell 6—are installed at prescribed locations in vacuum chamber 1, the locations at which respective cells are arranged and the directions faced thereby being set such that molecular beams discharged from these respective cells 3, 4, 5, 6 scatter in such manner as to produce uniform distributions as they are directed toward the same substrate 200 surface which is held by substrate manipulator 2.

Respective cell shutters 7 are installed at the fronts (between the cell and the substrate surface) of the respective discharge ports of the Group III molecular beam source cells, these being Ga cell 3 and In cell 4; opening and closing of those respective cell shutters 7 making it possible to radiate and interrupt molecular beams directed toward the substrate 200 surface from respective cells 3, 4. When in the normal, or ready, state, respective cell shutters 7 interrupt molecular beams from respective cells 3, 4, preventing them from being radiated toward substrate 200. Note that cell shutters 7 are shutters constructed similarly to those ordinarily used in MBE apparatuses.

Beam choppers 8, controlling radiation and interruption of molecular beam(s) exiting respective cells 5, 6 and directed toward substrate 200, are respectively installed at the fronts (between the cell and the substrate surface) of the respective discharge ports of the Group V molecular beam source cells, these being As cell 5 and P cell 6.

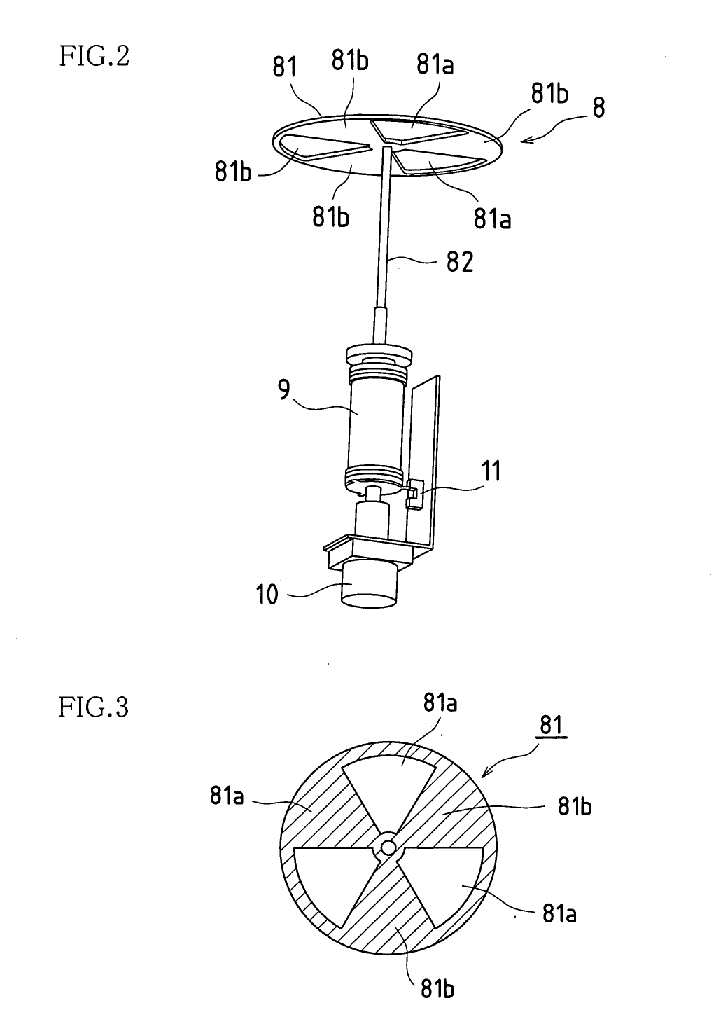

As shown in FIGS. 2 and 3, beam chopper 8 may comprise rotating vane assembly 81 and rotating shaft 82, and may be introduced into vacuum chamber 1 by way of magnetically coupled rotary feedthrough 9.

Magnetically coupled rotary feedthrough 9 serves as drive transmission mechanism for transmitting torque from motor 10 to rotating shaft 82 of beam chopper 8. Magnets (not shown), for magnetic coupling, within rotary feedthrough 9 are arranged at angular pitch 120° in the rotational direction.

Rotating vane assembly 81 of beam chopper 8 is in the form of a disk in which three fan-shaped cutouts 81a are provided in rotationally symmetric fashion with respect to the center of rotation thereof, the regions between respective cutouts 81a being occluding portions 81b which interrupt molecular beam(s). Rotating vane assembly 81 is rotated by driving force from motor 10, and is constructed so as to allow three molecular beam pulses to be discharged therefrom per rotation.

Attached to rotary feedthrough 9 is rotation detecting sensor 11 making it possible to measure molecular beam pulses produced by rotation of beam chopper 8 (rotating vane assembly 81) as electrical signal(s). Furthermore, by making rotation of motor 10 synchronous and measuring rotational pulses, it is possible to apply delay(s) between pulses, making it possible to obtain molecular beam pulse reproduceability with good precision.

Moreover, by controlling motor 10, it is possible to cause rotating vane assembly 81 of beam chopper 8 to advance in rotational fashion by prescribed angle(s), and it is also possible during continuous rotation to control rotational speed. Furthermore, beam choppers 8, when in their normal, or ready, states, interrupt molecular beams from As cell 5 and P cell 6, preventing them from radiating toward substrate 200 (i.e., occluding portions 81b of rotating vane assemblies 81 are at locations covering discharge ports of respective cells 5, 6); but when rotating vane assembly or assemblies 81 is/are rotated ⅙ of a rotation from such ready location(s), cutout(s) 81a of rotating vane assembly or assemblies 81 will be located in front of discharge port(s) of respective cell(s) 5, 6, permitting molecular beam(s) from respective cell(s) 5, 6 to reach the surface of substrate 200.

Here, in the present example, because magnets at magnetically coupled rotary feedthrough 9 are disposed at intervals of 120° in the rotational direction, consistent with which rotating vane assembly 81 utilizing three pulses per rotation is used, the arrangement of magnets within rotary feedthrough 9 being made to agree with the rotational period of cutouts 81a of rotating vane assembly 81, even where magnet(s) (magnetic coupler(s)) at magnetically coupled rotary feedthrough 9 is/are removed therefrom it will nonetheless be possible to attach same with good reproduceability.

### Crystal Growth

GaInP Crystal Growth

When using molecular beam epitaxy growth apparatus(es) constructed as shown in FIG. 1 to epitaxially grow GaInP crystal(s) on substrate surface(s), substrate 200 held by substrate manipulator 2 is first heated to a temperature of 500° C. as would be the case with an ordinary MBE apparatus; and as substrate 200 is rotated at a speed of 30 rotations per minute, beam chopper 8 at P cell 6 is moved by an amount corresponding to ⅙ of a rotation, permitting molecular beam(s) from P cell 6 to reach the surface of substrate 200.

Next, molecular beam(s) is/are discharged from P cell 6, causing P to be radiated onto the substrate 200 surface in sufficient quantity or quantities as necessary for epitaxial growth. Quantity or quantities of molecular beam(s) discharged from P cell 6 is/are monitored by measuring vacuum indicated by vacuum gauge(s) (not shown) installed at vacuum chamber 1. In the present example, P molecular beam(s) is/are discharged until vacuum is 1.5×10⁻⁶ Pa; and with the system in this state, respective cell shutters 7, 7 of Ga cell 3, which has previously been heated to 900° C., and In cell 4, which has previously been heated to 800° C., are simultaneously opened and closed, radiation of respective Ga and In molecular beams onto the substrate 200 surface causing epitaxial growth of GaInP crystal(s) on the substrate 200 surface. Deposition rate at this time is 1 μ/hour.

Note that crystal deposition rate(s) and/or alloy ratio(s) of Ga and In within crystal may be controlled by controlling respective material temperatures at Ga cell 3 and In cell 4. Moreover, as crystal deposition rate and/or alloy ratio may also vary depending upon amounts of materials with which source cells are charged and so forth, control may be carried out taking such factors into consideration as well.

GaInAsP Crystal Growth

When using molecular beam epitaxy growth apparatus(es) constructed as shown in FIG. 1 to epitaxially grow GaInAsP crystal(s) on substrate surface(s), substrate 200 is first heated and made to rotate as described above; and with the system in this state, molecular beam(s) is/are discharged from P cell 6 in sufficient quantity or quantities as necessary for epitaxial growth. With the system in this state, vacuum gauge(s) is/are used to measure molecular beam quantity, adjusting same to 1.5×10⁻⁶ Pa. Thereafter, molecular beam discharge from P cell 6 is stopped by means of valve(s) internal to the cell.

Next, in similar fashion, vacuum gauge(s) is/are used to confirm that molecular beam quantity from As cell 5 has been adjusted so as to attain 5×10⁻⁶ Pa, and molecular beams are thereafter discharged from both As cell 5 and P cell 6, respective beam choppers 8 being used to cause mutual pulsing thereof. In the present example, respective beam choppers 8, 8 are both set to a rotational speed of 20 rotations per minute (rotational speed of motors 10) to achieve a period of intermittency of 1 second, and a delay is set so as to cause the signal from rotation detecting sensor 11 at As cell 5 to lag the signal from rotation detecting sensor 11 at P cell 6 by 0.5 second (a phase shift of ½), causing As molecular beam(s) and P molecular beam(s) to be supplied to the substrate 200 surface in alternating fashion.

Moreover, with the system in this state, respective cell shutters 7, 7 of Ga cell 3 and In cell 4 are simultaneously opened and closed as was the case for GaInP described above, radiation of respective Ga and In molecular beams onto the substrate 200 surface causing epitaxial growth of GaInAsP crystal(s). Deposition rate at this time was 1 μ/hour.

Note that in the present example as well, crystal deposition rate(s) and/or alloy ratio(s) of Ga and In within crystal(s) may be controlled by controlling respective material temperatures at Ga cell 3 and In cell 4. Moreover, as crystal deposition rate and/or alloy ratio may also vary depending upon amounts of materials with which source cells are charged and so forth, control may be carried out taking such factors into consideration as well.

Here, during epitaxial growth, owing to apparatus configuration and/or cell dimensions, temperature(s) employed, molecular beam velocity or velocities, evacuation (exhaust) rate(s), cell placement, and/or the like, it may be that use of perfectly synchronous alternating pulses will result in failure to achieve proper epitaxial growth. Furthermore, with regard to alloy ratio(s) within crystal(s) as well, it may be that the ratio between As and P will be other than 1:1. In such situations, it may be efficacious to employ the stratagem of delaying radiation of molecular beam(s) from As cell 5 relative to radiation of molecular beam(s) from P cell 6.

For example, whereas a delay of 0.5 second was employed in the foregoing example, adjustment of alloy ratio(s) of As and P may be carried out by causing this to be 0.45 second. However, if residence time(s) of molecular beam(s) at the surface of substrate 200 is/are exceeded, this may interfere with ability to carry out epitaxial growth.

### Other Examples of Beam Choppers

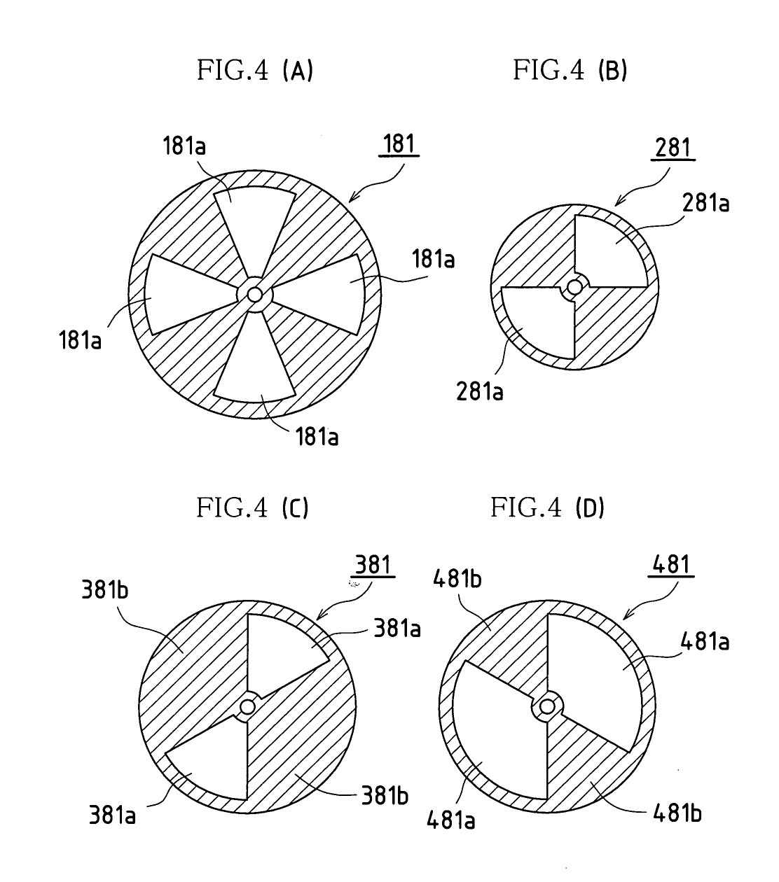

Other examples of rotating vane assemblies for beam choppers are shown at FIG. 4 (A) through (D).

Characteristic of rotating vane assembly 181 at FIG. 4 (A) is that it is in the form of a disk in which four fan-shaped cutouts 181a are provided in rotationally symmetric fashion with respect to the center of rotation thereof, being constructed so as to allow four molecular beam pulses to be discharged therefrom for each rotation of the beam chopper. In the present example, because magnets are arranged at 90° period(s), this will be effective when magnetically coupled rotary feedthrough(s) is/are employed. Furthermore, when used in combination with bellows-type rotary feedthrough(s) or other such situations, because life is determined by number of rotations and rotational speed, employment of rotating vane assembly 181 discharging four pulses makes it possible to anticipate increased life.

Characteristic of rotating vane assembly 281 at FIG. 4 (B) is that it is in the form of a disk in which two fan-shaped cutouts 281a are provided in rotationally symmetric fashion with respect to the center of rotation thereof, being constructed so as to allow two molecular beam pulses to be discharged therefrom for each rotation of the beam chopper. In the present example, because diameter of rotating vane assembly 281 can be made small, it is capable of accommodating reduction in weight of rotating portion(s) and/or spatial restrictions such as might exist in situations where there would be physical interference at the interior of the vacuum chamber or the like.

Characteristic of rotating vane assembly 381 at FIG. 4 (C) is that it is in the form of a disk in which two fan-shaped cutouts 381a are provided in rotationally symmetric fashion with respect to the center of rotation thereof, being constructed such that the areas of occluding portions 381b between the two cutouts 381a are increased so as to cause the ratio between discharge and blocking of molecular beam(s) during the period of intermittency to be approximately 1:2. In the present example, because during respective supply of molecular beams from As cell 5 and P cell 6 shown in FIG. 1 to the substrate surface it is possible to impart some degree of space (gaps) between supply of As molecular beam(s) and P molecular beam(s), this can be efficaciously utilized when apparatus discharge rate(s) are low and residence time(s) of molecular beam(s) at the substrate surface is/are large.

Characteristic of rotating vane assembly 481 at FIG. 4 (D) is that it is in the form of a disk in which two fan-shaped cutouts 481a are provided in rotationally symmetric fashion with respect to the center of rotation thereof, being constructed such that the areas of occluding portions 481b between the two cutouts 481a are decreased so as to cause the ratio between discharge and blocking of molecular beam(s) during the period of intermittency to be approximately 2:1. By adopting a configuration in which rotating vane assembly or assemblies 481 as at the present example and rotating vane assembly or assemblies 381 as at the aforementioned FIG. 4 (C) are used, rotating vane assembly or assemblies 481 of FIG. 4 (D) being employed at As cell 5 shown in FIG. 1 and rotating vane assembly or assemblies 381 of FIG. 4 (C) being employed at P cell 6, it is possible to make the ratio of durations of As and P molecular beam pulses that are radiated toward the substrate surface be 2:1. Where exhaust capability is sufficiently quick, this will make it possible to anticipate also being able to achieve an alloy ratio of 2:1 between As and P within crystal(s).

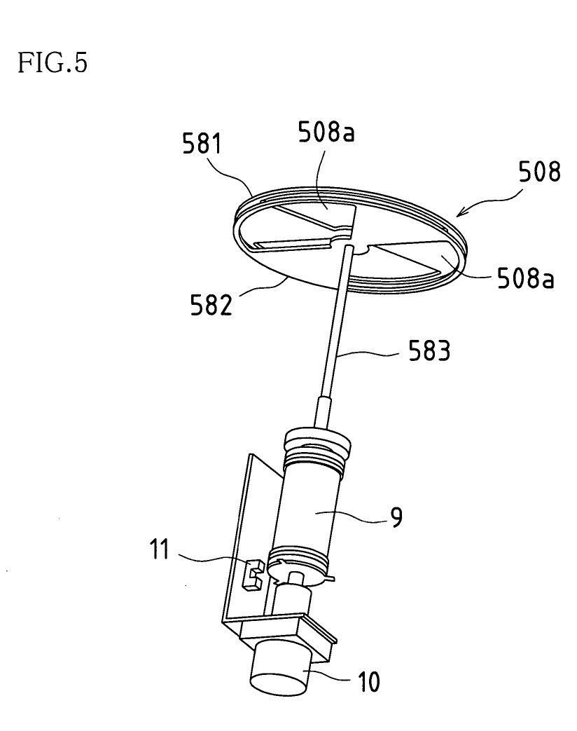

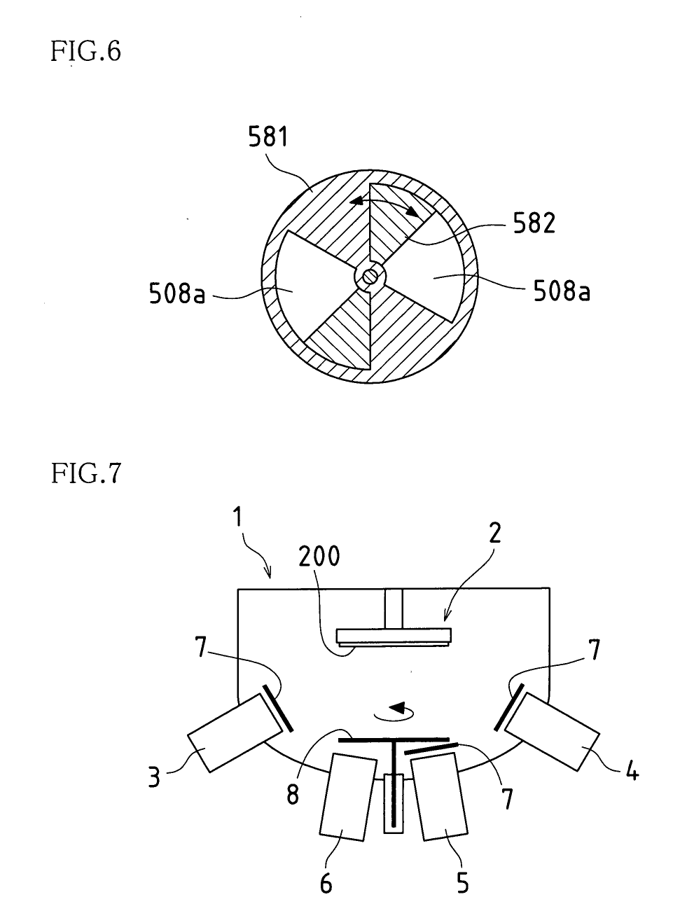

FIG. 5 is an oblique view showing another example of a beam chopper, and FIG. 6 is a front view of rotating vane assemblies used in that beam chopper.

Characteristic of beam chopper 508 of the present example is that it has upper rotating vane assembly 581 and lower rotating vane assembly 582, these two rotating vane assemblies 581, 582 being attached in coaxial fashion to the same rotating shaft 583 so as to be stacked one atop the other with a gap therebetween.

Both upper rotating vane assembly 581 and lower rotating vane assembly 582 have the same configuration as was the case at the aforementioned FIG. 4 (D). Furthermore, it is possible to move lower rotating vane assembly 582 relative to upper rotating vane assembly 581 (in rotary slide fashion), movement of that lower rotating vane assembly 582 relative to upper rotating vane assembly 581 making it possible to vary apparent size(s) of cutout(s) 508a in nonstepwise fashion over a range that is from approximately ⅓ to ⅔ of overall rotating vane assembly area. Accordingly, by using beam chopper 508 of the present example, it will be possible to control relative alloy ratios of As and P over the aforementioned range. Furthermore, by combining such beam chopper(s) 508 with the aforementioned delayed pulse technique, it is possible to adjust the ratio of As to Group V material(s) overall within the range from 25% to 75%.

### EMBODIMENT 2

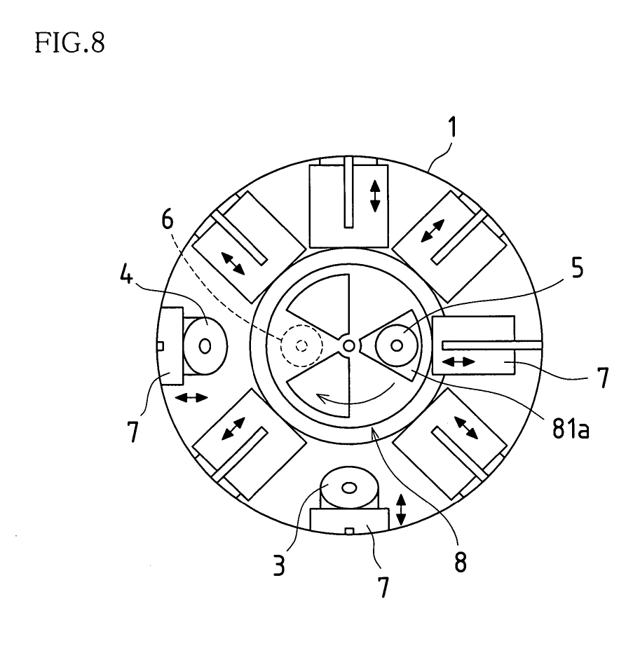

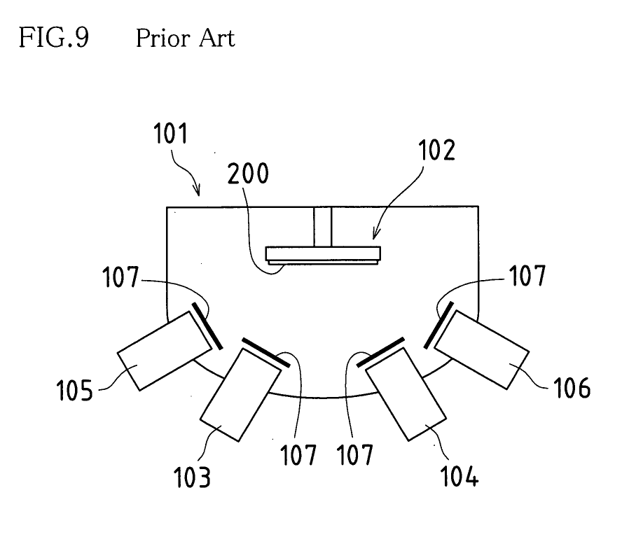

FIGS. 7 and 8 are respectively a front view and a plan view showing in schematic fashion a different exemplary constitution for a molecular beam epitaxy growth apparatus in accordance with the embodiment 2.

The molecular beam epitaxy growth apparatus of the present example is equipped with vacuum chamber 1, substrate manipulator 2, Ga cell (Group II molecular beam source cell) 3, In cell (Group III molecular beam source cell) 4, As cell (Group V molecular beam source cell) 5, P cell (Group V molecular beam source cell) 6, and so forth.

Vacuum chamber 1 is evacuated to 2×10⁻⁹ Pa with all heater(s) (not shown) turned OFF. Substrate manipulator 2 is installed in the upper central region of vacuum chamber 1.

Substrate manipulator 2 has built thereinto substrate heating mechanism(s) and substrate rotating mechanism(s) (neither of which is shown), permitting substrate 200, which is held by this substrate manipulator 2, to be maintained at constant temperature and to be rotated at constant speed.

Group V molecular beam source cells, these being As cell 5 and P cell 6, are arranged so as to be oriented more or less vertically at location(s) in the lower central region of vacuum chamber 1 in front of substrate 200 (at location(s) facing the surface of substrate 200). Furthermore, As cell 5 and P cell 6 are disposed such that the positional relationship therebetween is symmetric (180° symmetry) with respect to the center of vacuum chamber 1.

Group III molecular beam source cells, these being Ga cell 3 and In cell 4, are arranged peripherally with respect to As cell 5 and P cell 6 such that molecular beams respectively discharged from this Ga cell 3 and this In cell 4, as well as from the aforementioned As cell 5 and P cell 6, scatter in such manner as to produce uniform distributions as they are directed toward the same substrate 200 surface which is held by substrate manipulator 2.

Respective cell shutters 7 are installed at the fronts (between the cell and the substrate surface) of the respective discharge ports of Ga cell 3 and In cell 4; opening and closing of those respective cell shutters 7 making it possible to radiate and interrupt molecular beam(s) directed toward the substrate 200 surface from respective cells 3, 4. When in the normal, or ready, state, respective cell shutters 7 interrupt molecular beams from respective cells 3, 4, preventing them from being radiated toward substrate 200.

Beam chopper 8, controlling radiation and interruption of molecular beam(s) discharged from respective cells 5, 6 and directed toward substrate 200, is installed at the fronts (between the cell and the substrate surface) of the respective discharge ports of As cell 5 and P cell 6. Beam chopper 8 is identical in construction to that at the aforementioned FIG. 2, and is capable of alternately interrupting molecular beams discharged from As cell 5 and P cell 6 which are disposed symmetrically at the center of vacuum chamber 1.

Moreover, in the present example, rotation of beam chopper 8 causes As molecular beam(s) and P molecular beam(s) to be supplied in alternating fashion to the substrate 200 surface; and with the system in this state, respective cell shutters 7, 7 of Ga cell 3 and In cell 4 are simultaneously opened and closed, radiation of respective Ga and In molecular beams onto the substrate 200 surface causing epitaxial growth of GaInAsP crystal(s) on the substrate 200 surface.

As described above, because As cell 5 and P cell 6, molecular beams therefrom being pulsed (subjected to intermittency control) through use of beam chopper 8, are installed at location(s) more or less in front of substrate 200, the molecular beam epitaxy growth apparatus of the present example makes it possible to achieve more uniformly distributed intermittent molecular beam(s). Furthermore, because control of two molecular beam source cells, these being As cell 5 and P cell 6, is carried out by a single beam chopper 8, there being no need for external synchronization, it is possible to synchronously control intermittent molecular beams internally and in highly accurate fashion. However, with the constitution of the present example, because it would otherwise be impossible to simultaneously block molecular beams from As cell 5 and P cell 6, cell shutter(s) may be installed at either or both of As cell 5 and P cell 6; and in the constitution of FIGS. 7 and 8, cell shutter 7 is installed at As cell 5. But note that installation of such cell shutter(s) would be unnecessary in the event that the molecular beam source cell(s) employed have internal valve(s) and/or other such closing mechanism(s).

The present embodiment(s) is/are not limited to Groups III-V compound semiconductor crystal(s) such as GaInP crystal(s), GaInAsP crystal(s), and/or the like, but may also be effectively employed to obtain Groups II-VI compound semiconductor crystal(s).

The present invention may be embodied in a wide variety of forms other than those presented herein without departing from the spirit or essential characteristics thereof. The foregoing embodiments and working examples, therefore, are in all respects merely illustrative and are not to be construed in limiting fashion. The scope of the present invention being as indicated by the claims, it is not to be constrained in any way whatsoever by the body of the specification. All modifications and changes within the range of equivalents of the claims are moreover within the scope of the present invention.

1. A molecular beam epitaxy growth apparatus causing one or more crystals to be grown on one or more substrate surfaces as a result of radiation of one or more molecular beams from a plurality of molecular beam source cells onto at least one of the substrate surface or surfaces, the molecular beam epitaxy growth apparatus comprising one or more control mechanism:
controlling molecular beam radiation and/or interruption so as to cause intermittent radiation of at least one of the molecular beam or beams from at least a portion of the plurality of molecular beam source cells; and
controlling radiation and/or interruption of at least a portion of the molecular beams from at least a portion of the plurality of molecular beam source cells so as to be mutually substantially synchronous and/or have substantially identical periods at the molecular beam source cells.

2. A molecular beam epitaxy growth apparatus according to claim 1 wherein:
at least one of the control mechanism or mechanisms possesses one or more beam choppers having one or more rotating vane assemblies causing intermittent radiation of at least one of the molecular beam or beams.

3. A molecular beam epitaxy growth apparatus according to claim 2 wherein:
at least one of the rotating vane assembly or assemblies of at least one of the beam chopper or choppers is more or less in the form of a disk having one or more cutouts; and
at least a portion of the rotating vane assembly or assemblies is arranged such that rotation of at least a portion of the rotating vane assembly or assemblies causes at least a portion of the cutout or cutouts to be presented at at least one prescribed period along at least one path traveled by at least a portion of the molecular beam or beams from at least a portion of the molecular beam source cells.

4. A molecular beam epitaxy growth apparatus according to claim 2 wherein:
at least one of the beam chopper or choppers comprises at least two rotating vane assemblies, each of which is in the form of a disk having one or more cutouts; and
the at least two rotating vane assemblies are arranged in more or less coaxial fashion.

5. A molecular beam epitaxy growth apparatus according to claim 3 further comprising:
at least one magnetically coupled rotary feedthrough rotating at least one of the rotating vane assembly or assemblies;
wherein at least one period at which one or more magnets within at least one of the rotary feedthrough or feedthroughs are arranged is made to substantially agree with at least one period at which at least a portion of the cutout or cutouts of at least one of the rotating vane assembly or assemblies is arranged.

6. A molecular beam epitaxy growth apparatus according to claim 1 wherein:
one or more Groups II-VI compound semiconductors and/or one or more Groups III-V compound semiconductors is or are crystallized and grown.

7. A molecular beam epitaxy growth apparatus according to claim 6 wherein:
one or more Group II material molecular beams and/or one or more Group III material molecular beams is or are continuously radiated from at least a portion of the molecular beam source cells; and
one or more Group VI material molecular beams and/or one or more Group V material molecular beams is or are intermittently radiated from at least a portion of the molecular beam source cells.

8. A method of controlling one or more molecular beam epitaxy growth apparatuses according to claim 1 wherein:
at least one period of intermittency of at least one of the intermittently radiated molecular beam or beams is controlled so as to be not more than 8 seconds.
